(19) United States
(12) Patent Application Publication
(10) Pub. No.: US 2025/0318369 A1
(43) Pub. Date: Oct. 9, 2025

(54) DISPLAY DEVICE AND ELECTRONIC DEVICE

(71) Applicant: Samsung Display Co., LTD., Yongin-si (KR)

(72) Inventors: DOOSUB CHOI, Yongin-si (KR); SANGMIN KANG, Yongin-si (KR); JINTAE KIM, Yongin-si (KR); YOUNGEUN NAM, Yongin-si (KR); JAEYONG YANG, Yongin-si (KR); SANGYONG LEE, Yongin-si (KR); SEUL LEE, Yongin-si (KR)

(73) Assignee: Samsung Display Co., LTD., Yongin-si (KR)

(21) Appl. No.: 19/089,495

(22) Filed: Mar. 25, 2025

(30) Foreign Application Priority Data
Apr. 4, 2024 (KR) 10-2024-0045838

(51) Int. Cl. H10K 59/126; H10K 59/124; H10K 59/80

(52) U.S. Cl. CPC H10K 59/126; H10K 59/124; H10K 59/873

(57) ABSTRACT

A display device includes a window including a module area and a display area adjacent to the module area, a display panel disposed below the window, including a module hole overlapping the module area, and including an electrostatic discharge pattern layer surrounding the module hole in plan view and receiving a voltage, and a functional module disposed below the window and overlapping the module area and the module hole.

### CROSS-REFERENCE TO RELATED APPLICATION(S)

This application claims priority to and benefits of Korean Patent Application No. 10-2024-0045838 under 35 USC § 119, filed on Apr. 4, 2024, in the Korean Intellectual Property Office (KIPO), the entire disclosure of which is incorporated herein by reference.

### BACKGROUND

### 1. Technical Field

Embodiments relate to a display device. More specifically, embodiments relate to a display device that provides visual information and an electronic device including the display device.

### 2. Description of the Related Art

A display device may include a display panel that displays an image, a window that protects the display panel, and a functional module that provides various functions to a user. For example, the functional module may include a camera module, a sensor module, or the like, and may detect or recognize a user, an object, or the like located in front of the display device through an area that transmits incident external light.

While using the display device, static electricity may be accumulated in the window due to friction with a user, an external object, or the like, and the functional module may be affected by light generated from the display panel.

### SUMMARY

Embodiments provide a display device with improved reliability.

Embodiments provide an electronic device including the display device.

However, embodiments are not limited to those set forth herein. The above and other embodiments will become more apparent to one of ordinary skill in the art to which the disclosure pertains by referencing the detailed description of the disclosure given below.

A display device according to an embodiment includes a window including a module area and a display area adjacent to the module area, a display panel disposed below the window, including a module hole overlapping the module area, and including an electrostatic discharge pattern layer surrounding the module hole in plan view and receiving a voltage, and a functional module disposed below the window and overlapping the module area and the module hole.

In an embodiment, the electrostatic discharge pattern layer may surround the display area in plan view.

In an embodiment, the electrostatic discharge pattern layer may extend continuously.

In an embodiment, the voltage of the electrostatic discharge pattern layer may be a ground voltage.

In an embodiment, the voltage may be a swing voltage having a level between a first voltage and a second voltage having different levels from each other.

In an embodiment, the module area may include a central area and a peripheral area surrounding the central area in plan view, and the window may include a window light blocking pattern layer overlapping the peripheral area.

In an embodiment, the electrostatic discharge pattern layer may overlap the peripheral area.

In an embodiment, the display device may further include a plate disposed below the display panel and including an opening overlapping the module area and the module hole, and a side pattern layer overlapping the module area and covering a side surface of the display panel adjacent to the module hole and a side surface of the plate adjacent to the opening.

In an embodiment, the side pattern layer may extend from the window to the plate.

In an embodiment, the functional module may be disposed in the module hole.

A display device according to an embodiment includes a window including a module area, a display area surrounding the module area in plan view, and a non-display area surrounding the display area in plan view, a display panel disposed below the window and including an electrostatic discharge pattern layer disposed along an edge portion of the non-display area in plan view and receiving a voltage, and a functional module disposed below the window and overlapping the module area.

In an embodiment, the display panel may include a module hole overlapping the module area and penetrating the display panel in a thickness direction.

In an embodiment, the electrostatic discharge pattern layer may be further disposed along an edge portion of the module hole in plan view.

In an embodiment, the electrostatic discharge pattern layer may extend continuously.

In an embodiment, the voltage of the electrostatic discharge pattern layer may be a ground voltage.

In an embodiment, the voltage may be a swing voltage having a level between a first voltage and a second voltage having different levels from each other.

In an embodiment, the module area may include a central area and a peripheral area surrounding the central area in plan view, and the window may include a window light blocking pattern layer overlapping the peripheral area.

In an embodiment, the electrostatic discharge pattern layer may be further disposed along the peripheral area in plan view.

In an embodiment, the display device may further include a plate disposed below the display panel and including an opening overlapping the module area and the module hole, and a side pattern layer overlapping the module area and covering a side surface of the display panel adjacent to the module hole and a side surface of the plate adjacent to the opening.

In an embodiment, the side pattern layer may extend from the window to the plate.

An electronic device according to an embodiment includes a display device and a power module that supplies power to the display device. The display device includes a module area and a display area adjacent to the module area, a display panel disposed below the window, including a module hole overlapping the module area, and including an electrostatic discharge pattern layer surrounding the module hole in plan view and receiving a voltage, and a functional module disposed below the window and overlapping the module area and the module hole.

In a display device according to embodiments, the display device may include a display panel including a module hole and including an electrostatic discharge pattern layer. The electrostatic discharge pattern layer may surround an edge portion of the display panel and an edge portion of the module hole in plan view, and a voltage may be applied to the electrostatic discharge pattern layer. Accordingly, since influence of static electricity generated from outside on the display panel may be blocked, the display panel may be protected from electrostatic discharge, and reliability of the display device may be improved.

### BRIEF DESCRIPTION OF THE DRAWINGS

FIG. 1 is a schematic plan view illustrating a display device according to an embodiment.

FIG. 2 is a schematic exploded perspective view of the display device of FIG. 1.

FIG. 3 is a schematic plan view of a display panel included in the display device of FIG. 1.

FIG. 4 is an enlarged schematic plan view of area A of FIG. 3.

FIG. 5 is a schematic cross-sectional view taken along line I-I′ of FIG. 1.

FIG. 6 is a schematic cross-sectional view taken along line II-II′ of FIG. 3.

FIG. 7 is a schematic cross-sectional view illustrating a display device according to an embodiment.

FIG. 8 is a schematic block diagram illustrating an electronic device according to an embodiment.

FIG. 9 is a schematic view illustrating electronic devices according to embodiments.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z—axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

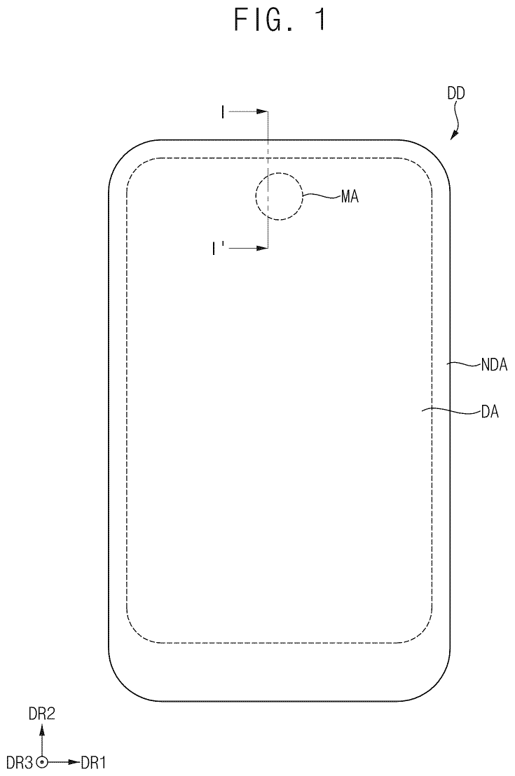

FIG. 1 is a schematic plan view illustrating a display device according to an embodiment.

Referring to FIG. 1, a display device DD may include a display area DA and a non-display area NDA. The display area DA may be an area that displays an image, and the non-display area NDA may be an area that does not display an image.

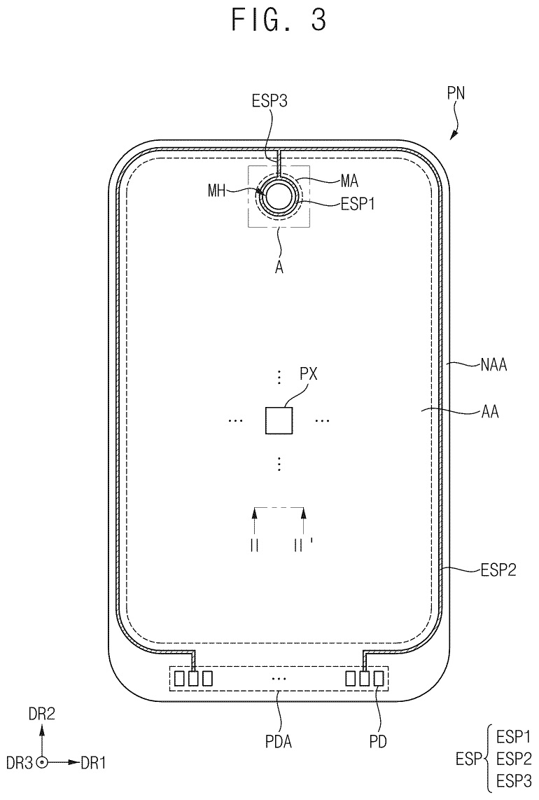

Pixels (e.g., pixels PX of FIG. 3) that display light may be disposed in the display area DA. For example, the pixels may be repeatedly disposed along a first direction DR1 and a second direction DR2 intersecting the first direction DR1, and accordingly, an image may be displayed in a third direction DR3 intersecting each of the first direction DR1 and the second direction DR2 in the display area DA. For example, the first direction DR1, the second direction DR2, and the third direction DR3 may be perpendicular to each other. In the description, “in plan view” may mean a case viewed from the third direction DR3.

The non-display area NDA may be disposed around the display area DA. For example, the non-display area NDA may surround the display area DA in plan view. A driver for displaying an image of the display area DA may be disposed in the non-display area NDA.

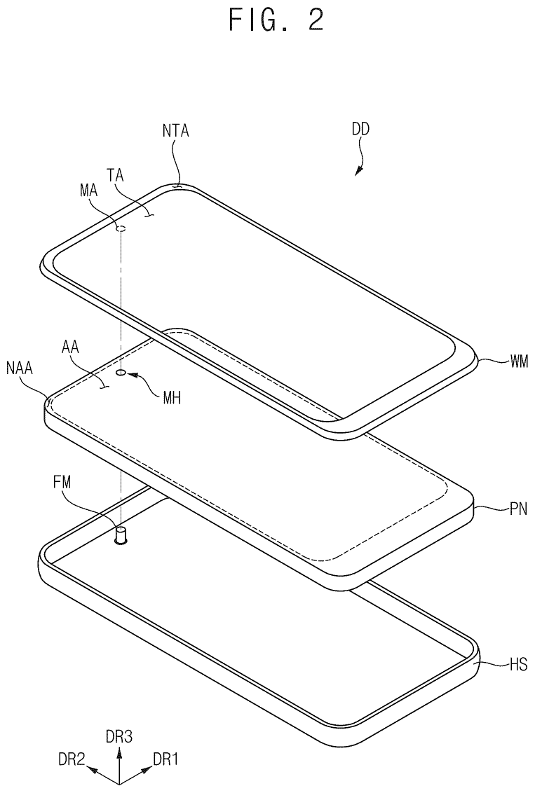

The display device DD may further include a module area MA. The module area MA may be disposed around the display area DA. For example, the display area DA may surround the module area MA in a plan view. For example, the module area MA may be an area that does not display an image. A functional module (e.g., a functional module FM of FIG. 2) may be disposed in the module area MA. The module area MA may be an area that receives an external signal required for the functional module or provides a signal output from the functional module to outside.

Although FIG. 1 illustrates that the display device DD includes one module area MA and the module area MA is defined at an upper central part of the display device DD, embodiments are not limited thereto. For example, the display device DD may include module areas MA, and the module area MA may be defined at various areas such as an upper right part, an upper left part, a lower right part, a lower left part, or the like of the display device DD.

Although FIG. 1 illustrates that the module area MA has a circular planar shape, embodiments are not limited thereto. For example, the module area MA may have various shapes such as a polygonal planar shape, an elliptical planar shape, or the like.

FIG. 2 is a exploded schematic perspective view of the display device of FIG. 1.

Referring to FIGS. 1 and 2, the display device DD may include a window WM, a display panel PN, and a housing HS.

The window WM may include an optically transparent material. For example, the window WM may include glass, plastic, sapphire, or the like. The window WM may include a material having a relatively high transmittance, and may transmit light generated from the display panel PN. The window WM may protect the display panel PN from an external impact.

The window WM may have a single layer structure or a multi-layer structure. For example, the window WM may include plastic films bonded with an adhesive, or may include a glass substrate a plastic film bonded with an adhesive. The window WM may further include a functional coating layer. For example, the functional coating layer may include an anti-fingerprint layer, an anti-reflection layer, a hard coating layer, or the like.

The window WM may include a transmissive area TA and a bezel area NTA. The transmissive area TA may be an area having a relatively high transmittance, and the bezel area NTA may be an area having a relatively low transmittance. For example, the transmissive area TA may be an area that is optically transparent, and the bezel area NTA may be an area that is not optically transparent.

The bezel area NTA may be disposed around the transmissive area TA. For example, the bezel area NTA may surround the transmissive area TA in plan view. In plan view, the transmissive area TA may overlap the display area DA and the module area MA, and the bezel area NTA may overlap the non-display area NDA. For example, the transmissive area TA may correspond to the display area DA and the module area MA, and the bezel area NTA may correspond to the non-display area NDA.

The display panel PN may be disposed below the window WM. The display panel PN may be adjacent to the window WM in a direction opposite to the third direction DR3. The display panel PN may display an image.

The display panel PN may include an active area AA and a non-active area NAA. The active area AA may be an area that displays an image, and the non-active area NAA may be an area that does not display an image.

The non-active area NAA may be disposed around the active area AA. For example, the non-active area NAA may surround the active area AA in plan view. In a plan view, the active area AA may overlap the display area DA, and the non-active area NAA may overlap the non-display area NDA. For example, the active area AA may correspond to the display area DA, and the non-active area NAA may correspond to the non-display area NDA.

The display panel PN may include the pixels disposed in the active area AA, and may include the driver disposed in the non-active area NAA. The image displayed in the active area AA may be visually recognized from the outside through the transmissive area TA. The non-active area NAA may be covered by the bezel area NTA, and may not be visually recognized from the outside.

The display panel PN may define (or include) a module hole MH. The module hole MH may penetrate the display panel PN in a thickness direction (e.g., the third direction DR3). The module hole MH may overlap the module area MA in plan view. The module area MA may be defined as an area in which the module hole MH is formed. For example, the module hole MH may be defined in the active area AA.

The housing HS may be disposed below the display panel PN. The housing HS and the window WM may be coupled to form an exterior of the display device DD. For example, the housing HS and the window WM may be coupled to provide an internal space, and the display panel PN may be accommodated in the internal space.

The housing HS may include a material having relatively high rigidity. For example, the housing HS may include metal, glass, plastic, or the like. The housing HS may protect components of the display device DD accommodated in the internal space from an external impact.

The housing HS may include a functional module FM. The functional module FM may overlap the module area MA and the module hole MH in plan view. For example, at least a portion of the functional module FM may be accommodated (or disposed) in the module hole MH. However, embodiments are not limited thereto, and in another example, the functional module FM may be disposed below the display panel PN.

The functional module FM may receive an external input transmitted through the module area MA, or may provide an output through the module area MA. For example, the functional module FM may include a camera module that captures an image of (or recognizes) an object located in front of the display device DD, a face recognition sensor module that detects a user's face, a pupil recognition sensor module that detects a user's pupil, an acceleration sensor module and a geomagnetic sensor module that determine a movement of the display device DD, a proximity sensor module and an infrared sensor module that detect proximity to the front of the display device DD, and an illuminance sensor module that measures a degree of external brightness, or the like.

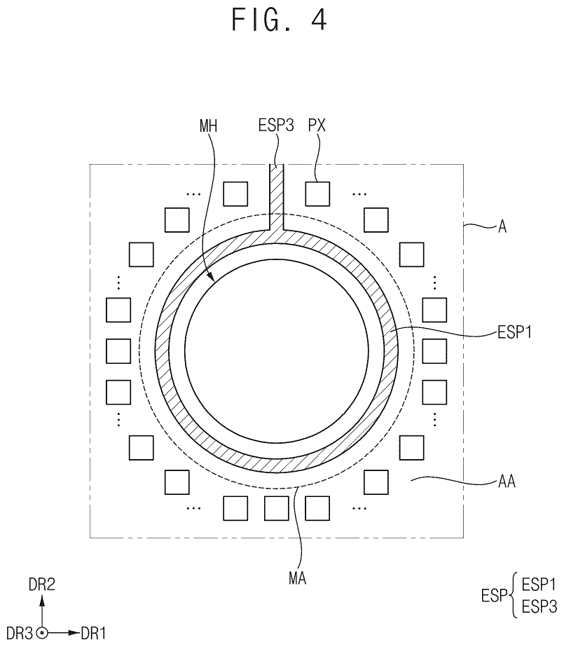

FIG. 3 is a schematic plan view of a display panel included in the display device of FIG. 1. FIG. 4 is an enlarged schematic plan view of area A of FIG. 3.

Referring to FIGS. 1, 3, and 4, the display panel PN may include pixels PX and pads PD. The pixels PX may be disposed in the active area AA, and the pads PD may be disposed in the non-active area NAA. For example, the pixels PX may be arranged along the first direction DR1 and the second direction DR2, and the pads PD may be arranged along the first direction DR1. The non-active area NAA may include a pad area PDA in which the pads PD are disposed.

The module hole MH may overlap the module area MA in a plan view. The module hole MH may be defined in the module area MA. The active area AA may surround the module area MA in a plan view. For example, the pixels PX may not be disposed in the module area MA.

The display panel PN may further include a signal line electrically connected to each of the pixels PX to transmit an electrical signal to the pixels PX. For example, the signal line may include a data line, a power line, or the like.

The pads PD may be electrically connected to the signal line. The display panel PN may provide an electrical signal provided from the outside to the pixels PX through the pads PD.

In an embodiment, the display panel PN may further include an electrostatic discharge pattern layer ESP. The electrostatic discharge pattern layer ESP may include a first electrostatic discharge pattern layer ESP1, a second electrostatic discharge pattern layer ESP2, and a third electrostatic discharge pattern layer ESP3. For example, the electrostatic discharge pattern layer ESP may extend continuously. The electrostatic discharge pattern layer ESP may include a metal, an alloy, a conductive metal nitride, a conductive metal oxide, a transparent conductive material, or the like. These may be used alone or in combination with each other.

In a plan view, the first electrostatic discharge pattern layer ESP1 may overlap the module area MA, and the second electrostatic discharge pattern layer ESP2 may overlap the non-active area NAA. In a plan view, the first electrostatic discharge pattern layer ESP1 may be disposed to surround the module hole MH, and the second electrostatic discharge pattern layer ESP2 may be disposed to surround the active area AA. In a plan view, the first electrostatic discharge pattern layer ESP1 may be disposed along an edge portion of the module hole MH, and the second electrostatic discharge pattern layer ESP2 may be disposed along an edge portion of the non-active area NAA.

The third electrostatic discharge pattern layer ESP3 may connect the first electrostatic discharge pattern layer ESP1 and the second electrostatic discharge pattern layer ESP2. For example, the third electrostatic discharge pattern layer ESP3 may partially overlap the module area MA, the active area AA, and the non-active area NAA in a plan view. The electrostatic discharge pattern layer ESP may extend from the module area MA to the non-active area NAA through the third electrostatic discharge pattern layer ESP3.

The electrostatic discharge pattern layer ESP may be electrically connected to at least one of the pads PD. For example, the first electrostatic discharge pattern layer ESP1 may be electrically connected to at least one of the pads PD through the second and third electrostatic discharge pattern layers ESP2 and ESP3. The display panel PN may provide an electrical signal provided from the outside to the electrostatic discharge pattern layer ESP through at least one of the pads PD.

In an embodiment, the electrostatic discharge pattern layer ESP may be applied with a voltage of a specific level. The electrostatic discharge pattern layer ESP may form an electric field. For example, the electrostatic discharge pattern layer ESP may be applied with a ground voltage. In another example, the electrostatic discharge pattern layer ESP may be applied with a swing voltage having a level between a first voltage and a second voltage, which have different levels from each other. The swing voltage may have a voltage swing range between the first voltage and the second voltage. However, embodiments are not limited thereto, and the electrostatic discharge pattern layer ESP may be applied with various voltages that form an electric field in consideration of factors such as a polarity of charges accumulated on an outer surface of the display device DD, an effect of a voltage applied to the electrostatic discharge pattern layer ESP on the display panel PN, or the like.

In an embodiment, the electrostatic discharge pattern layer ESP may protect the display panel PN from electrostatic discharge. The electrostatic discharge may be a phenomenon in which charge transfer occurs in a short moment in case that a charged object and another object having a potential difference come into contact, and may damage an element (e.g., a transistor) disposed in the active area AA, a driver (e.g., a gate driver) disposed in the non-active area NAA, or the like, thereby causing malfunctions, defects, or the like of the display panel PN. In the description, the electrostatic discharge pattern layer ESP disposed along an edge portion of the display panel PN and an edge portion of the module hole MH to which a voltage is applied may block the influence of static electricity generated from the outside on the display panel PN.

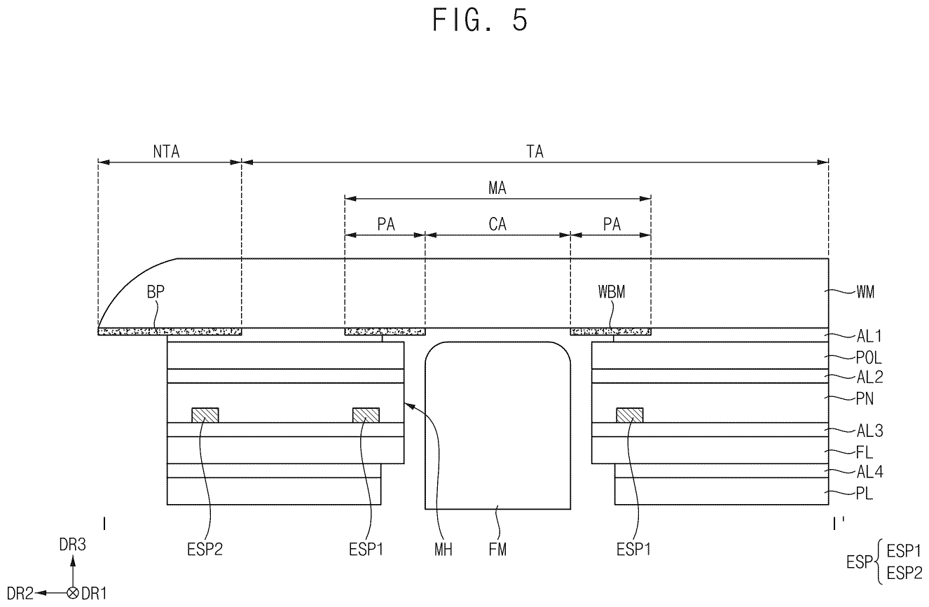

FIG. 5 is a schematic cross-sectional view taken along line I-I′ of FIG. 1.

Referring to FIGS. 1, 3, and 5, the display device DD may include the window WM, a polarizing layer POL, the display panel PN, a film layer FL, a plate PL, a first adhesive layer AL1, a second adhesive layer AL2, a third adhesive layer AL3, and a fourth adhesive layer AL4.

The window WM may be disposed on the display panel PN to protect the display panel PN. The window WM may include the transmissive area TA including the module area MA and the bezel area NTA.

The window WM may include a bezel pattern layer BP. The bezel pattern layer BP may be disposed on a lower surface of the window WM (e.g., a surface adjacent to the polarizing layer POL of the window WM), and may define the bezel area NTA. In a plan view, the bezel pattern layer BP may overlap the bezel area NTA, and may not overlap the transmissive area TA. The bezel pattern layer BP may include a light blocking material. For example, the bezel pattern layer BP may include an organic material having a black color. The bezel pattern layer BP may cover the non-active area NAA so as not to be visually recognized from the outside.

The module area MA may include a central area CA and a peripheral area PA. The peripheral area PA may be adjacent to the central area CA. For example, the peripheral area PA may surround the central area CA in a plan view.

The window WM may further include a window light blocking pattern layer WBM. The window light blocking pattern layer WBM may overlap the module area MA in a plan view. The window light blocking pattern layer WBM may be disposed on the lower surface of the window WM, and may define the peripheral area PA. In a plan view, the window light blocking pattern layer WBM may overlap the peripheral area PA, and may not overlap the central area CA. For example, the window light blocking pattern layer WBM may overlap at least a portion of the module hole MH in a plan view. However, embodiments are not limited thereto, and in another example, the window light blocking pattern layer WBM may not overlap the module hole MH in a plan view.

The window light blocking pattern layer WBM may include a light blocking material. For example, the window light blocking pattern layer WBM may include an organic material having a black color. The window light blocking pattern layer WBM may prevent light leaked through the module hole MH from being visually recognized from the outside through the peripheral area PA, and may prevent the functional module FM from being affected by unintended light.

The polarizing layer POL may be disposed below the window WM. The polarizing layer POL may reduce reflectance of external light incident on the window WM. For example, the polarizing layer POL may prevent external light incident through a front surface of the display device DD from being reflected by components included in the display panel PN to be visually recognized from the outside.

For example, the polarizing layer POL may include a phase retarder or a polarizer. The phase retarder may be a film type or a liquid crystal coating type, and may include a λ/2 phase retarder or a λ/4 phase retarder. The polarizer may be a film type, and may include a stretchable synthetic resin film. The polarizing layer POL may define (or include) a first opening overlapping the module area MA and the module hole MH in a plan view. The first opening may penetrate the polarizing layer POL in a thickness direction (e.g., the third direction DR3).

The display panel PN may be disposed below the polarizing layer POL. The active area AA and the non-active area NAA of the display panel PN may correspond to the display area DA and the non-display area NDA of the display device DD, respectively. The display panel PN may define (or include) the module hole MH overlapping the central area CA of the module area MA in a plan view.

The display panel PN may include the electrostatic discharge pattern layer ESP. The first electrostatic discharge pattern layer ESP1 which is a portion of the electrostatic discharge pattern layer ESP may overlap the peripheral area PA of the module area MA in a plan view. The first electrostatic discharge pattern layer ESP1 may be disposed to surround the central area CA and the module hole MH in a plan view. The first electrostatic discharge pattern layer ESP1 may extend along the edge portion of the module hole MH in a plan view. The second electrostatic discharge pattern layer ESP2, which is another portion of the electrostatic discharge pattern layer ESP, may be disposed to surround the active area AA in a plan view. The second electrostatic discharge pattern layer ESP2 may extend along the edge portion (or an edge portion of the display device DD) of the display panel PN in a plan view.

The electrostatic discharge pattern layer ESP may protect the display panel PN from electrostatic discharge. For example, in case that friction occurs between the display device DD and a user, an external object, or the like, electric charges may be accumulated in the window WM, and damage may occur to the display panel PN due to electrostatic discharge.

For example, a path through which static electricity flows into the display panel PN from the outside is shielded by an electric field formed by the electrostatic discharge pattern layer ESP to which a voltage is applied, and thus an influence that occurs due to electrostatic discharge in an element (e.g., a transistor), a driver (e.g., a gate driver), a circuit, or the like disposed in the active area AA and the non-active area NAA of the display panel PN may be minimized. For example, the first electrostatic discharge pattern layer ESP1 may prevent static electricity from flowing into the active area AA from the outside through the module area MA, and the second electrostatic discharge pattern layer ESP2 may prevent static electricity from flowing into the active area AA and the non-active area NAA from the outside through the non-active area NAA.

The film layer FL may be disposed below the display panel PN. The film layer FL may include a plastic film. For example, the film layer FL may include a polyimide resin. The film layer FL may protect a lower surface of the display panel PN (e.g., a surface adjacent to the film layer FL of the display panel PN). For example, the film layer FL may prevent damage to the lower surface of the display panel PN during a manufacturing process of the display panel PN. The film layer FL may define (or include) a second opening overlapping the module area MA and the module hole MH in a plan view. The second opening may penetrate the film layer FL in a thickness direction (e.g., the third direction DR3).

The plate PL may be disposed below the film layer FL. The plate PL may include a material having relatively high rigidity. For example, the plate PL may include metal, glass, plastic, or the like. The plate PL may support the display panel PN. The plate PL may define (or include) a third opening overlapping the module area MA and the module hole MH in a plan view. The third opening may penetrate the plate PL in a thickness direction (e.g., the third direction DR3).

The first adhesive layer AL1 may be disposed between the window WM and the polarizing layer POL, and may couple (or bond) the window WM and the polarizing layer POL. The first adhesive layer AL1 may define (or include) a fourth opening overlapping the module area MA and the module hole MH in a plan view. The fourth opening may penetrate the first adhesive layer AL1 in a thickness direction (e.g., the third direction DR3).

The second adhesive layer AL2 may be disposed between the polarizing layer POL and the display panel PN, and may couple (or bond) the polarizing layer POL and the display panel PN. The second adhesive layer AL2 may define (or include) a fifth opening overlapping the module area MA and the module hole MH in a plan view. The fifth opening may penetrate the second adhesive layer AL2 in a thickness direction (e.g., the third direction DR3).

The third adhesive layer AL3 may be disposed between the display panel PN and the film layer FL, and may couple (or bond) the display panel PN and the film layer FL. The third adhesive layer AL3 may define (or include) a sixth opening overlapping the module area MA and the module hole MH in a plan view. The sixth opening may penetrate the third adhesive layer AL3 in a thickness direction (e.g., the third direction DR3).

The fourth adhesive layer AL4 may be disposed between the film layer FL and the plate PL, and may couple (or bond) the film layer FL and the plate PL. The fourth adhesive layer AL4 may define (or include) a seventh opening overlapping the module area MA and the module hole MH in a plan view. The seventh opening may penetrate the fourth adhesive layer AL4 in a thickness direction (e.g., the third direction DR3).

For example, each of the first, second, third, and fourth adhesive layers AL1, AL2, AL3, and AL4 may be optically transparent. For example, each of the first, second, third, and fourth adhesive layers AL1, AL2, AL3, and AL4 may include a pressure sensitive adhesive (PSA), an optically clear adhesive (OCA), an optically clear resin (OCR), or the like.

The functional module FM may be disposed below the window WM. The functional module FM may overlap the central area CA of the module area MA in a plan view. The first to seventh openings and the module hole MH may provide a space in which the functional module FM is disposed. For example, the first to seventh openings and the module hole MH may expose a portion of the lower surface of the window WM. For example, the functional module FM may be inserted into and fixed to at least a portion of the space. For example, the module area MA may include an area in which the polarizing layer POL, the display panel PN, the film layer FL, the plate PL, and the first, second, third, and fourth adhesive layers AL1, AL2, AL3 and AL4 are not disposed. In the central area CA of the module area MA, the polarizing layer POL, the display panel PN, the film layer FL, the plate PL, and the first, second, third, and fourth adhesive layers AL1, AL2, AL3 and AL4 may not be disposed, and the functional module FM may be disposed.

Although FIG. 5 illustrates a length in the second direction DR2 of each of the first opening defined by polarizing layer POL, the second opening defined by the film layer FL, the fifth opening defined by the second adhesive layer AL2, the sixth opening defined by the third adhesive layer AL3, and the module hole MH defined by the display panel PN is smaller than a length in the second direction DR2 of each of the third opening defined by the plate PL, the fourth opening defined by the first adhesive layer AL1, and the seventh opening defined by the fourth adhesive layer AL4 in the second direction DR2, embodiments are not limited thereto. For example, a size (e.g., a width, a diameter, or the like) of each of the first to seventh openings and the module hole MH may be variously modified.

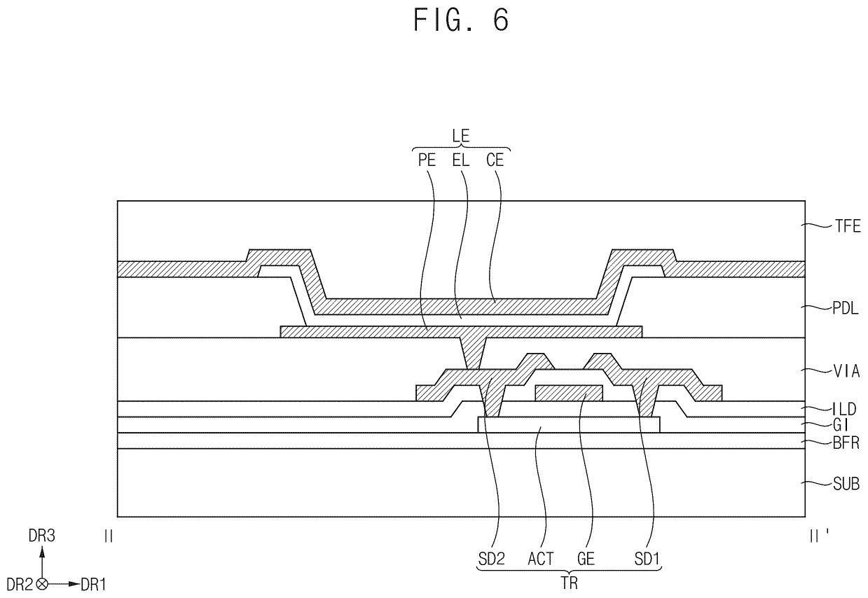

FIG. 6 is a schematic cross-sectional view taken along line II-II′ of FIG. 3. FIG. 6 may be a schematic cross-sectional view schematically illustrating a portion of the display panel PN.

Referring to FIGS. 3, 5, and 6, the display panel PN may include a substrate SUB, a buffer layer BFR, a transistor TR, a gate insulating layer GI, an interlayer insulating layer ILD, a via insulating layer VIA, a light emitting element LE, a pixel defining layer PDL, and an encapsulation layer TFE.

For example, the transistor TR may include an active pattern layer ACT, a gate electrode GE, a first electrode SD1, and a second electrode SD2, and the light emitting element LE may include a pixel electrode PE, a light emitting layer EL, and a common electrode CE.

The substrate SUB may include a transparent material or an opaque material. For example, the substrate SUB may include plastic, glass, quartz, silicon, or the like. These may be used alone or in combination with each other.

The buffer layer BFR may be disposed on the substrate SUB. The buffer layer BFR may prevent metal atoms, impurities, or the like from diffusing into the transistor TR. For example, the buffer layer BFR may improve a flatness of a surface of the substrate SUB in case that the surface of the substrate SUB is not uniform. The buffer layer BFR may include an inorganic material such as silicon oxide (SiOₓ), silicon nitride (SiNₓ), silicon oxynitride (SiOₓN_{y}), or the like. These may be used alone or in combination with each other.

The active pattern layer ACT may be disposed on the buffer layer BFR. The active pattern layer ACT may include a source area, a drain area, and a channel area between the source area and the drain area. The active pattern layer ACT may include a silicon semiconductor material or an oxide semiconductor material. Examples of the silicon semiconductor material may include amorphous silicon, polycrystalline silicon, or the like. Examples of the oxide semiconductor material may include indium gallium zinc oxide (IGZO), indium tin zinc oxide (ITZO), or the like. These may be used alone or in combination with each other.

The gate insulating layer GI may be disposed on the active pattern layer ACT, and may cover the active pattern layer ACT. The gate insulating layer GI may include an inorganic material such as silicon oxide, silicon nitride, silicon oxynitride, or the like. These may be used alone or in combination with each other.

The gate electrode GE may be disposed on the gate insulating layer GI. The gate electrode GE may overlap the channel area of the active pattern layer ACT in a plan view. The gate electrode GE may include a metal, an alloy, a conductive metal nitride, a conductive metal oxide, a transparent conductive material, or the like. These may be used alone or in combination with each other.

The interlayer insulating layer ILD may be disposed on the gate electrode GE, and may cover the gate electrode GE. The interlayer insulating layer ILD may include an inorganic material such as silicon oxide, silicon nitride, silicon oxynitride, or the like. These may be used alone or in combination with each other.

The first electrode SD1 and the second electrode SD2 may be disposed on the interlayer insulating layer ILD. The first electrode SD1 may be connected to the source area of the active pattern layer ACT through a first contact hole penetrating the gate insulating layer GI and the interlayer insulating layer ILD. For example, the second electrode SD2 may be connected to the drain area of the active pattern layer ACT through a second contact hole penetrating the gate insulating layer GI and the interlayer insulating layer ILD. For example, each of the first electrode SD1 and the second electrode SD2 may include a metal, an alloy, a conductive metal nitride, a conductive metal oxide, a transparent conductive material, or the like. These may be used alone or in combination with each other.

Accordingly, the transistor TR including the active pattern layer ACT, the gate electrode GE, the first electrode SD1, and the second electrode SD2 may be disposed on the substrate SUB.

The via insulating layer VIA may be disposed on the interlayer insulating layer ILD, and may cover the first electrode SD1 and the second electrode SD2. The via insulating layer VIA may include an organic material such as a phenol resin, an acrylic resin, a polyimide resin, a polyamide resin, a siloxane resin, an epoxy resin, or the like. These may be used alone or in combination with each other.

The pixel electrode PE may be disposed on the via insulating layer VIA. The pixel electrode PE may be connected to the second electrode SD2 (or the first electrode SD1) through a contact hole penetrating the via insulating layer VIA. The pixel electrode PE may include a metal, an alloy, a conductive metal nitride, a conductive metal oxide, a transparent conductive material, or the like. These may be used alone or in combination with each other.

The pixel defining layer PDL may be disposed on the via insulating layer VIA, and may cover at least a portion of the pixel electrode PE. An opening exposing at least a portion of an upper surface of the pixel electrode PE may be defined in the pixel defining layer PDL. The pixel defining layer PDL may include an organic material or an inorganic material. For example, the pixel defining layer PDL may include an organic material such as an epoxy resin, a siloxane resin, or the like. In another example, the pixel defining layer PDL may include an organic material or an inorganic material including a light blocking material having a black color.

The light emitting layer EL may be disposed on the pixel electrode PE. The light emitting layer EL may be disposed on the pixel electrode PE exposed by the pixel defining layer PDL. The light emitting layer EL may include a material that emits light of a predetermined color.

The common electrode CE may be disposed on the light emitting layer EL. For example, the common electrode CE may be a plate electrode. The common electrode CE may include a metal, an alloy, a conductive metal nitride, a conductive metal oxide, a transparent conductive material, or the like. These may be used alone or in combination with each other.

Accordingly, the light emitting element LE including the pixel electrode PE, the light emitting layer EL, and the common electrode CE may be disposed on the substrate SUB. The light emitting element LE may be electrically connected to the transistor TR. The light emitting element LE may generate light corresponding to a driving current provided from the transistor TR.

The encapsulation layer TFE may be disposed on the common electrode CE. The encapsulation layer TFE may protect the light emitting element LE from external oxygen, moisture, or the like. The encapsulation layer TFE may include at least one inorganic layer and at least one organic layer. For example, the encapsulation layer TFE may have a structure in which inorganic layers and organic layers are alternately stacked.

In an embodiment, a layer on which the electrostatic discharge pattern layer ESP is disposed in the display panel PN may not be limited, and the electrostatic discharge pattern layer ESP may be disposed in various layers. For example, the electrostatic discharge pattern layer ESP may be formed through the same process as various electrodes included in the display panel PN.

The display device DD according to an embodiment may include the display panel PN including the electrostatic discharge pattern layer ESP. The electrostatic discharge pattern layer ESP may surround the edge portion of the display panel PN and the edge portion of the module hole MH defined in the display panel PN in a plan view, and a voltage may be applied to the electrostatic discharge pattern layer ESP. Accordingly, since the influence of static electricity generated from the outside on the display panel PN may be blocked, the display panel PN may be protected from electrostatic discharge, and reliability of the display device DD may be improved.

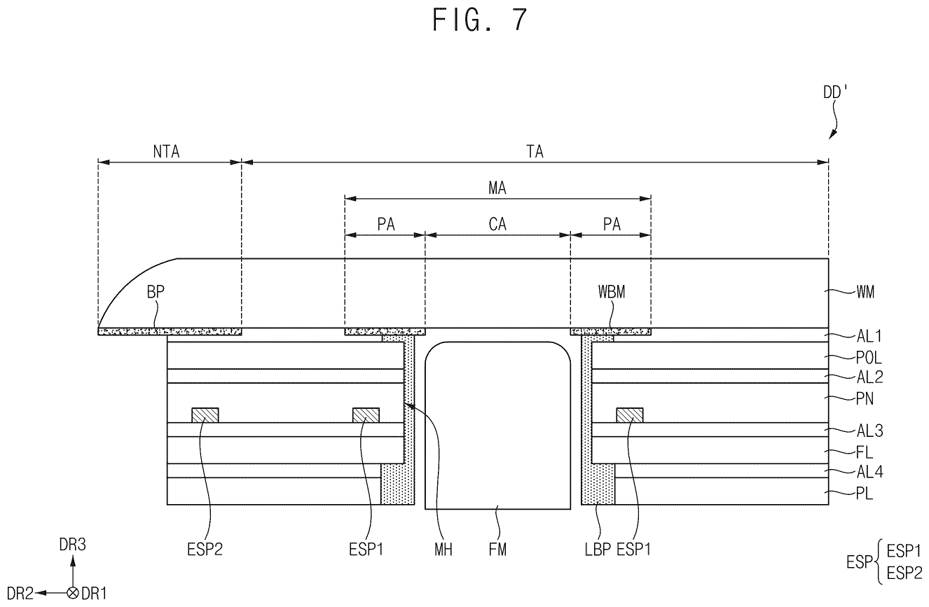

FIG. 7 is a schematic cross-sectional view illustrating a display device according to an embodiment. FIG. 7 may correspond to the schematic cross-sectional view of FIG. 5.

A display device DD' described with reference to FIG. 7 may be substantially the same as or similar to the display device DD described with reference to FIGS. 1, 2, 3, 4, 5, and 6 except for a side pattern layer LBP. Hereinafter, redundant descriptions are omitted or simplified for descriptive convenience.

Referring to FIG. 7, the display device DD′ may include a window WM, a polarizing layer POL, a display panel PN, a film layer FL, a plate PL, a first adhesive layer AL1, a second adhesive layer AL2, a third adhesive layer AL3, a fourth adhesive layer AL4, and the side pattern layer LBP.

The window WM may include a transmissive area TA including the module area MA and a bezel area NTA surrounding the transmissive area TA in a plan view. The module area MA may include a central area CA and a peripheral area PA surrounding the central area CA in a plan view.

The window WM may include a bezel pattern layer BP defining the transmissive area TA and the bezel area NTA and a window light blocking pattern layer WBM defining the central area CA and the peripheral area PA. For example, each of the bezel pattern layer BP and the window light blocking pattern layer WBM may include a light blocking material.

The polarizing layer POL may be disposed below the window WM, and the display panel PN may be disposed below the polarizing layer POL. The polarizing layer POL may define (or include) a first opening overlapping the module area MA in a plan view, and the display panel PN may define (or include) a module hole MH overlapping the module area MA in a plan view.

In an embodiment, the display panel PN may include an electrostatic discharge pattern layer ESP. The electrostatic discharge pattern layer ESP may include a first electrostatic discharge pattern layer ESP1 overlapping the peripheral area PA of the module area MA in a plan view and a second electrostatic discharge pattern layer ESP2 overlapping the bezel area NTA in a plan view. The first electrostatic discharge pattern layer ESP1 may surround the central area CA and the module hole MH in a plan view, and may extend along an edge portion of the module hole MH. The second electrostatic discharge pattern layer ESP2 may surround the transmissive area TA in a plan view, and may extend along an edge portion of the display panel PN. The first electrostatic discharge pattern layer ESP1 and the second electrostatic discharge pattern layer ESP2 may be connected to each other. For example, the electrostatic discharge pattern layer ESP may extend continuously.

In an embodiment, the electrostatic discharge pattern layer ESP may be applied with a voltage. For example, the electrostatic discharge pattern layer ESP may be applied with a voltage of a specific level or a ground voltage. In another example, the electrostatic discharge pattern layer ESP may be applied with a swing voltage having a level between a first voltage and a second voltage having different levels from each other. However, embodiments are not limited thereto.

The electrostatic discharge pattern layer ESP may form an electric field to protect the display panel PN from electrostatic discharge. For example, the first electrostatic discharge pattern layer ESP1 may prevent static electricity from flowing into the display panel PN from the outside through the module area MA, and the second electrostatic discharge pattern layer ESP2 may prevent static electricity from flowing into the display panel PN form the outside through the bezel area NTA.

The film layer FL may be disposed below the display panel PN, and the plate PL may be disposed below the film layer FL. The film layer FL and the plate PL may define (or include) a second opening and a third opening overlapping the module area MA in a plan view, respectively.

The first adhesive layer AL1 may be disposed between the window WM and the polarizing layer POL to couple (or bond) the window WM and the polarizing layer POL. The second adhesive layer AL2 may be disposed between the polarizing layer POL and the display panel PN to couple (or bond) the polarizing layer POL and the display panel PN. The third adhesive layer AL3 may be disposed between the display panel PN and the film layer FL to couple (or bond) the display panel PN and the film layer FL. The fourth adhesive layer AL4 may be disposed between the film layer FL and the plate PL to couple (or bond) the film layer FL and the plate PL. The first, second, third, and fourth adhesive layers AL1, AL2, AL3, and AL4 may define (or include) fourth, fifth, sixth, and seventh openings overlapping the module area MA in a plan view, respectively.

The functional module FM may be disposed below the window WM. The functional module FM may overlap the module area MA in a plan view. The functional module FM may be disposed in a space provided by the first to seventh openings and the module hole MH.

The side pattern layer LBP may be disposed in the first to seventh openings and the module hole MH. The side pattern layer LBP may cover side surfaces of the polarizing layer POL, the film layer FL, the plate PL, and the first, second, third, and fourth adhesive layers AL1, AL2, AL3, and AL4 adjacent to the first to seventh openings, respectively, and a side surface of the display panel PN adjacent to the module hole MH. In a plan view, the side pattern layer LBP may overlap the peripheral area PA, and may surround the functional module FM and the central area CA. For example, the functional module FM may be disposed in a space provided by the side pattern layer LBP.

The side pattern layer LBP may be in contact with the window WM. For example, the side pattern layer LBP may be in contact with the window light blocking pattern layer WBM. The side pattern layer LBP may extend from the window WM to the plate PL. For example, the side pattern layer LBP may be formed through an inkjet printing process.

In an embodiment, the side pattern layer LBP may include a non-conductive material. In case that electric charges are accumulated in the window WM due to external friction, electrostatic discharge may occur in the side pattern layer LBP, but the display panel PN may be protected by the first electrostatic discharge pattern layer ESP1. For example, the electrostatic discharge pattern layer ESP may shield a path through which static electricity flows into the display panel PN from the outside, thereby protecting the display panel PN from electrostatic discharge.

In an embodiment, the side pattern layer LBP may include a conductive material. In case that electric charges are accumulated in the window WM due to external friction, the electric charges may be moved to the plate PL along the side pattern layer LBP. For example, the electrostatic discharge pattern layer ESP may shield a path through which static electricity flows into the display panel PN from the outside, and the side pattern layer LBP may form an electrostatic discharge path, thereby protecting the display panel PN from electrostatic discharge.

In an embodiment, the side pattern layer LBP may include a light blocking material. For example, the side pattern layer LBP may block light generated in the display panel PN and traveling toward the functional module FM. Accordingly, a malfunction of the functional module FM due to light generated from the display panel PN may be prevented.

The display devices DD and DD′ according to embodiments may be applied to various electronic devices. An electronic device according to an embodiment may include the display device DD or the display device DD′ described above, and may further include a module or device having additional functions in addition to the display device DD or the display device DD′.

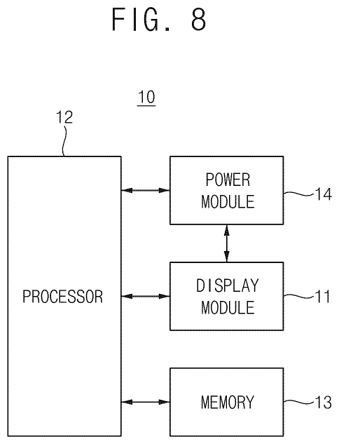

FIG. 8 is a schematic block diagram illustrating an electronic device according to an embodiment.

Referring to FIG. 10, an electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for an operation of the processor 12 or the display module 11. In case that the processor 12 executes an application stored in the memory 13, an image data signal and/or an input control signal may be transmitted to the display module 11, and the display module 11 may process the received signal and output image information through a display screen.

The power module 14 may include a power supply module such as a power adapter, a battery device, or the like and a power conversion module that converts power supplied by the power supply module to generate power necessary for an operation of the electronic device 10.

At least one of the components of the electronic device 10 described above may be included in the display device according to an embodiment described above. In addition, some of individual modules functionally included in one module may be included in the display device, and others may be provided separately from the display device. For example, the display device may include the display module 11, and the processor 12, the memory 13, and the power module 14 may be provided in form of other devices in the electronic device 10 other than the display device.

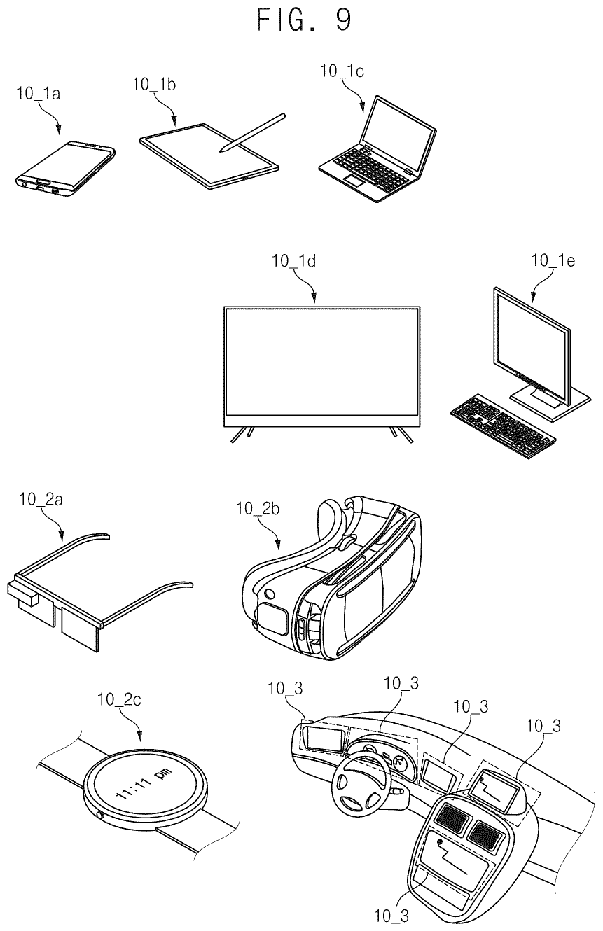

FIG. 9 is a schematic view illustrating electronic devices according to embodiments.

Referring to FIG. 9, various electronic devices to which the display device according to an embodiment is applied may include not only an image display electronic device, but also a wearable electronic device including a display module, a vehicle electronic device 10_3 including a display module, or the like. The image display electronic device may be a smartphone 10_1a, a tablet PC 10_1b, a laptop 10_1c, a TV 10_1d, a desk monitor 10_1e, or the like. The wearable electronic device may be smart glasses 10_2a, a head mounted display 10_2b, a smart watch 10_2c, or the like. The vehicle electronic device 10_3 may be a center information display (CID) disposed on a dashboard and center fascia of a vehicle, a room mirror display, or the like.

The description can be applied to various display devices and electronic devices. For example, the description is applicable to various display devices such as display devices for vehicles, ships and aircraft, portable communication devices, display devices for exhibition or information transmission, medical display devices, and the like.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a window including a module area and a display area adjacent to the module area;
a display panel disposed below the window, including a module hole overlapping the module area, and including an electrostatic discharge pattern layer surrounding the module hole in plan view and receiving a voltage; and
a functional module disposed below the window and overlapping the module area and the module hole.

2. The display device of claim 1, wherein the electrostatic discharge pattern layer surrounds the display area in plan view.

3. The display device of claim 1, wherein the electrostatic discharge pattern layer extends continuously.

4. The display device of claim 1, wherein the voltage of the electrostatic discharge pattern layer is a ground voltage.

5. The display device of claim 1, wherein the voltage is a swing voltage having a level between a first voltage and a second voltage having different levels from each other.

6. The display device of claim 1, wherein
the module area includes a central area and a peripheral area surrounding the central area in plan view, and
the window includes a window light blocking pattern layer overlapping the peripheral area.

7. The display device of claim 6, wherein the electrostatic discharge pattern layer overlaps the peripheral area.

8. The display device of claim 1, further comprising:
a plate disposed below the display panel and including an opening overlapping the module area and the module hole; and
a side pattern layer overlapping the module area and covering a side surface of the display panel adjacent to the module hole and a side surface of the plate adjacent to the opening.

9. The display device of claim 8, wherein the side pattern layer extends from the window to the plate.

10. The display device of claim 1, wherein the functional module is disposed in the module hole.

11. A display device comprising:
a window including a module area, a display area surrounding the module area, and a non-display area surrounding the display area in plan view;
a display panel disposed below the window and including an electrostatic discharge pattern layer disposed along an edge portion of the non-display area in plan view and receiving a voltage; and
a functional module disposed below the window and overlapping the module area.

12. The display device of claim 11, wherein the display panel includes a module hole overlapping the module area and penetrating the display panel in a thickness direction.

13. The display device of claim 12, wherein the electrostatic discharge pattern layer is further disposed along an edge portion of the module hole in plan view.

14. The display device of claim 11, wherein the electrostatic discharge pattern layer extends continuously.

15. The display device of claim 11, wherein the voltage of the electrostatic discharge pattern layer is a ground voltage.

16. The display device of claim 11, wherein the voltage is a swing voltage having a level between a first voltage and a second voltage having different levels from each other.

17. The display device of claim 11, wherein
the module area includes a central area and a peripheral area surrounding the central area in plan view, and
the window includes a window light blocking pattern layer overlapping the peripheral area.

18. The display device of claim 17, wherein the electrostatic discharge pattern layer is further disposed along the peripheral area in plan view.

19. The display device of claim 12, further comprising:
a plate disposed below the display panel and including an opening overlapping the module area and the module hole; and
a side pattern layer overlapping the module area and covering a side surface of the display panel adjacent to the module hole and a side surface of the plate adjacent to the opening.

20. The display device of claim 19, wherein the side pattern layer extends from the window to the plate.

21. An electronic device comprising:
a display device; and
a power module that supplies power to the display device,
wherein the display device includes:
a window including a module area and a display area adjacent to the module area;
a display panel disposed below the window, including a module hole overlapping the module area, and including an electrostatic discharge pattern layer surrounding the module hole in plan view and receiving a voltage; and
a functional module disposed below the window and overlapping the module area and the module hole.
